(19) United States
(12) Patent Application Publication
(10) Pub. No.: US 2013/0267160 A1
(43) Pub. Date: Oct. 10, 2013

(54) AIR DISTRIBUTION STRUCTURE OF INDUSTRIAL CABINET

(71) Applicant: KUO-CHUAN HUNG, TAIPEI HSIEN (TW)

(72) Inventor: KUO-CHUAN HUNG, TAIPEI HSIEN (TW)

(73) Assignee: CHUN LONG TECHNOLOGY CO., LTD., NEW TAIPEI CITY (TW)

(21) Appl. No.: 13/441,926

(22) Filed: Apr. 9, 2012

(51) Int. Cl. H05K 5/02

(52) U.S. Cl. 454/184

(57) ABSTRACT

An air distribution structure of an industrial cabinet comprises a bottom box having at least one air intake device and at least one duct, and the bottom box is disposed at the bottom of the industrial cabinet and has an air inlet and an air outlet coupled to the duct for sucking cold air proximate to the ground and delivering the cold air into the industrial cabinet uniformly to enhance the cool house effect. The duct has a size corresponding to the size of a plurality of pillars of the industrial cabinet, so that the duct will not occupy the internal using space of the industrial cabinet.

### BACKGROUND OF THE INVENTION

1. Field of the Invention

The present invention relates to the technical field of a housing of electric equipments or components, in particular to the air distribution structure of an industrial cabinet that sucks cold air from the bottom of an industrial cabinet into the cabinet uniformly through a duct installed on a side of the cabinet to improve a cool house effect.

2. Description of the Related Art

In general, the industrial computer cabinet is used for containing a plurality of electronic equipments such as industrial computers or severs, and the temperature in the industrial computer cabinets will be increased by the heat generated during the operation of the electronic equipments. To prevent abnormality of the electronic equipments due to high temperature, the industrial computer cabinets generally come with a plurality of extraction fans installed at the rear of the computer cabinets for extracting internal hot air from the rear to the outside, and an airflow is produced to drive external cold air to flow into the computer cabinets from the front side to dissipate the heat. However, the industrial computer cabinets are installed in an air-conditioned engine room of a constant temperature. With the characteristics of the rising hot air and the descending cold air, air sucked from the front side is not the cold air with the lowest temperature around, so that the internal temperature of industrial computer cabinet cannot be lowered immediately.

With reference to FIG. 1 for U.S. Pat. No. 7,226,353 B2 entitled “Cabinet for computer devices with air distribution device”, the cabinet 1 used for computer equipments comprises a duct 11 having a plurality of airholes 110 formed proximate to both sides of a front door 10, and a partition plate 12 for separating the bottom of the cabinet 1 for computer equipments into an air distribution chamber 13. The air distribution chamber 13 includes a pair of wind boxes 14 coupled to the vertical ducts 11 for sucking external cold air, and then the vertical ducts 11 are used for delivering the cold air to the front of the cabinet 1 for computer equipments, such that the cold air cannot be distributed uniformly into the cabinet 1 for computer equipments, and the cool house effect cannot be enhanced effectively. However, the vertical ducts 11 and the air distribution chamber 13 occupy the internal using space of the cabinet 1 for computer equipments, thus resulting in low space utilization.

### SUMMARY OF THE INVENTION

In view of the problems of the prior art, it is a primary objective of the present invention to provide an air distribution structure of an industrial cabinet, wherein after cold air outside the bottom of the industrial cabinet is sucked by an air intake device in the condition of not occupying any internal using space of the industrial cabinet, and then a vertical duct is used for delivering the cold air into each position inside the industrial cabinet to enhance the cool house effect of the cabinet.

To achieve the foregoing objective, the present invention provides an air distribution structure of an industrial cabinet installed inside the industrial cabinet, and the industrial cabinet comprises a pillar separately and vertically disposed at four corners of a top panel to define four sides, a door panel disposed at a front side, and a right panel, a left panel and a rear panel disposed on the remaining three sides respectively, and a plurality of electronic equipments disposed among the pillars to form a plurality of installation spaces, and the air distribution structure comprises a bottom box, at least one duct and at least one air intake device. The bottom box is coupled to the bottom of the pillars and has at least one air inlet and at least one air outlet. The duct is installed in at least one of the side panels other than the rear panel and disposed between the pillars, and an end of the duct is coupled to the air outlet, and a plurality of through holes is formed on a surface of the duct, and the duct has a size corresponding to the size of the pillars. The air intake device is installed inside the bottom box for producing a suction force to suck cold air near the ground from the air inlet, and the cold air is guided by the duct and delivered into the installation spaces uniformly to enhance the cool house effect of the cabinet.

Wherein, the air intake device is a vortex fan. The duct is installed on the door panel, and an end of the duct is separated from the air outlet when the door panel is opened, and coupled to the air outlet when the door panel is closed. Alternatively, two ducts are installed in the left panel and the right panel respectively, and an end of each duct is coupled to the air outlet. In addition, at least one wind outlet portion is disposed separately on the rear panel or the top panel. The air distribution structure of an industrial cabinet further comprises an airflow guide tube with an end coupled to the air inlet, and the other end coupled to a cold air source. If a plurality of industrial cabinets is used, the air distribution structure further comprises an air distribution tube coupled to the airflow guide tubes and the cold air source, and the industrial cabinets are connected to suck in cold air of a lower temperature to enhance the cool house effect of the cabinet significantly.

### BRIEF DESCRIPTION OF THE DRAWINGS

FIG. 1 is a schematic view of a cabinet for computer devices as disclosed in U.S. Pat. No. 7,226,353 B2;

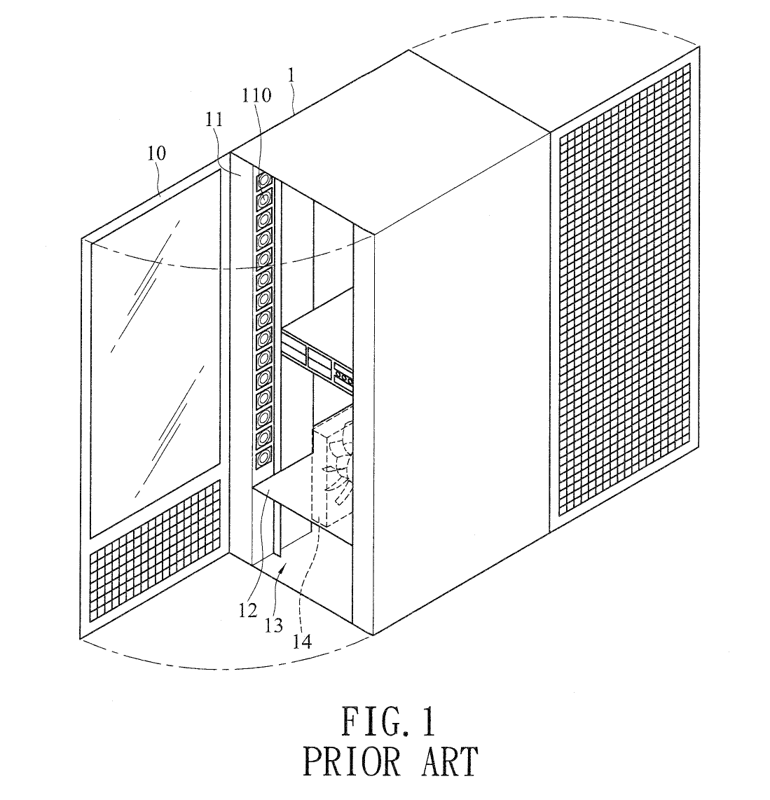

FIG. 2 is an exploded view of an exemplary embodiment of the present invention;

FIG. 3 is a schematic view of an exemplary embodiment of the present invention;

FIG. 4 is a cross-sectional view of an exemplary embodiment of the present invention;

FIG. 5 is a schematic view of another exemplary embodiment of the present invention; and

FIG. 6 is a schematic view of a further exemplary embodiment of the present invention.

### DETAILED DESCRIPTION OF THE PREFERRED EMBODIMENTS

The technical contents of the present invention will become apparent with the detailed description of preferred embodiments and the illustration of related drawings as follows.

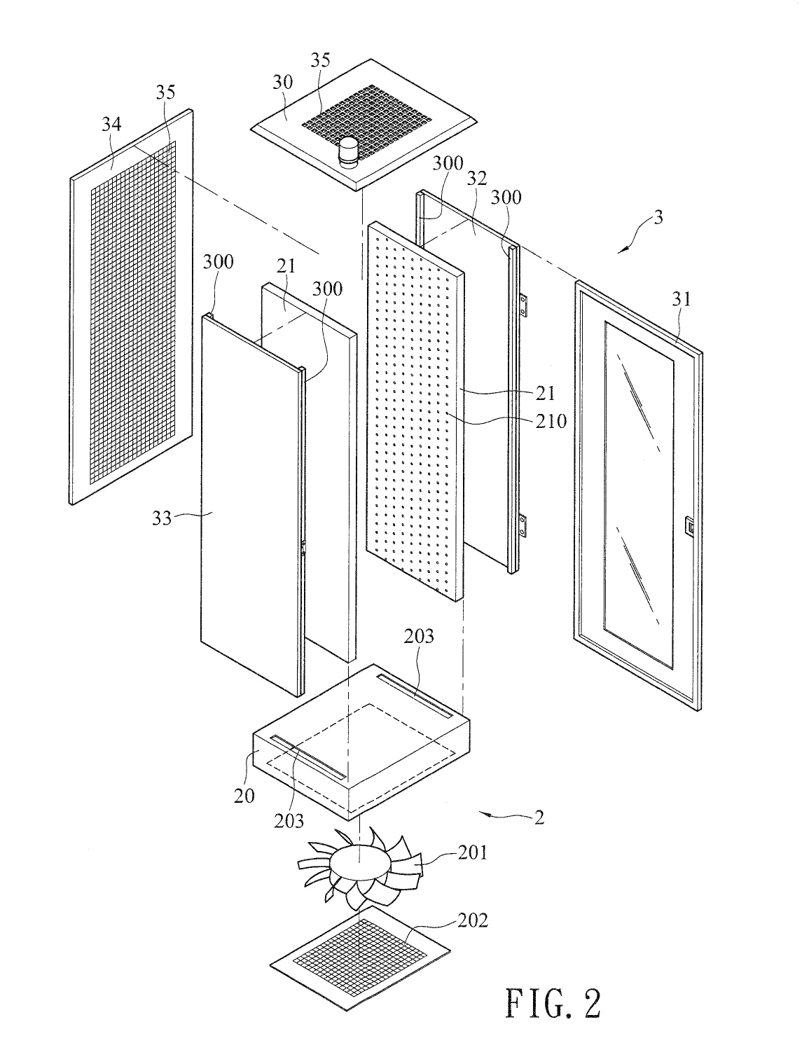

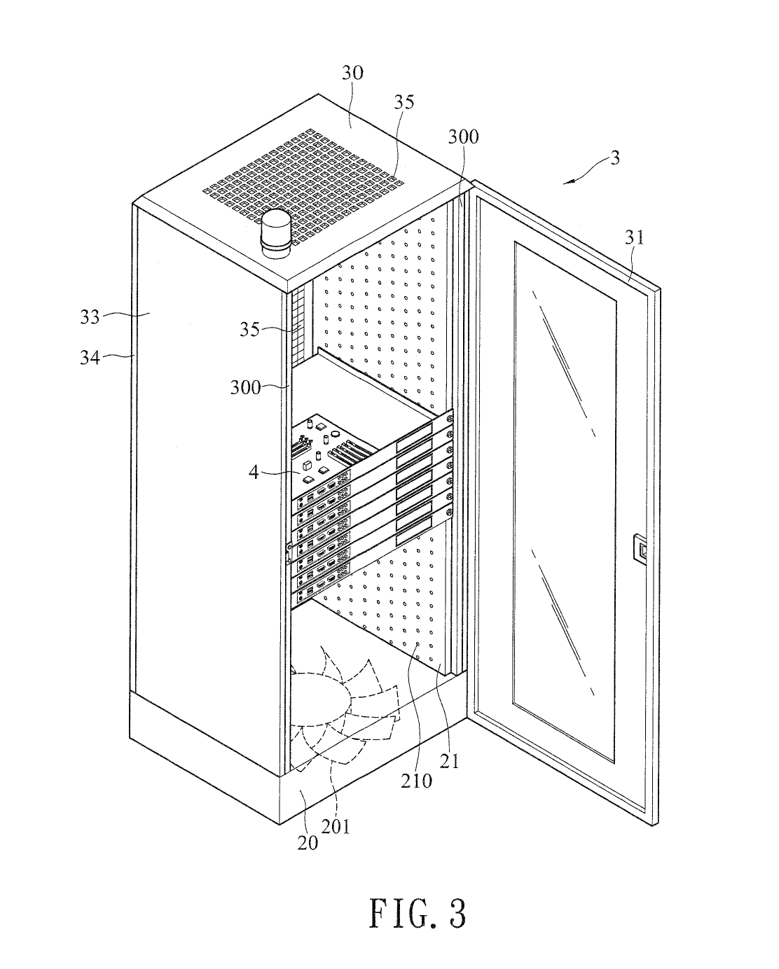

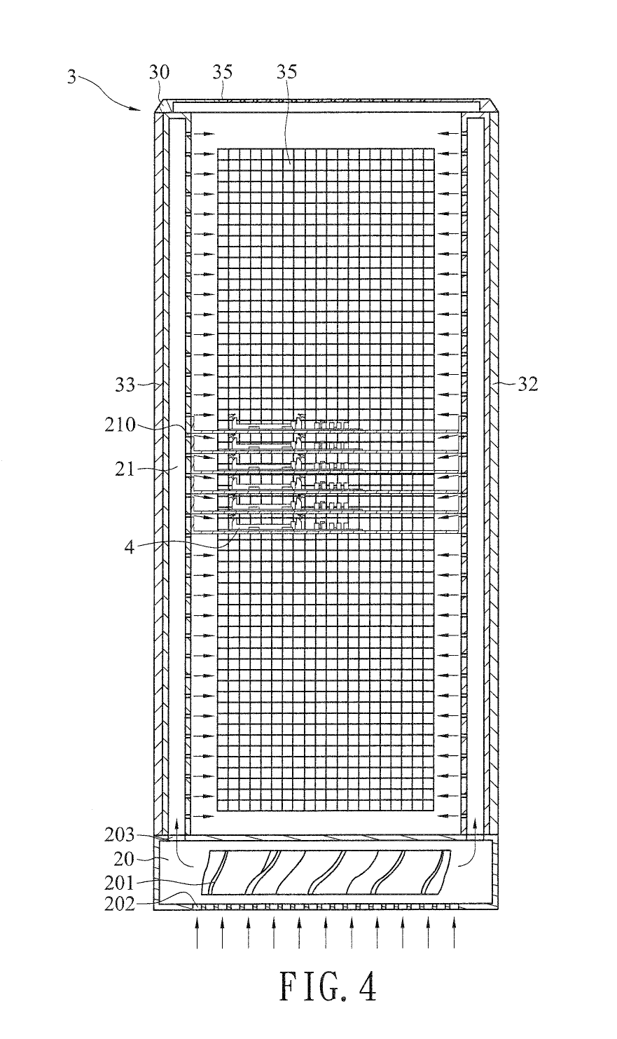

With reference to FIGS. 2 to 4 for an exploded view, a schematic view and a cross-sectional view of a preferred embodiment of the present invention respectively, the air distribution structure 2 of an industrial cabinet 3 is installed inside the industrial cabinet 3, and the industrial cabinet 3 is substantially a rectangular box having a top panel 30 disposed at the top, a door panel 31 disposed at the front, and a right panel 32, a left panel 33 and a rear panel 34 disposed on three remaining sides respectively. The rear panel 34 has a wind outlet portion 35 formed thereon and provided for discharging hot air released from a plurality of electronic equipments 4 inside the industrial cabinet 30. Pillars 300 are disposed separately and vertically from four corners of the top panel 30, and the wind outlet portion 35 is disposed at the center of the top panel 30 to expedite discharging the hot air. The corresponding electronic equipments 4 among the pillars 300 form a plurality of installation spaces.

The air distribution structure 2 comprises a bottom box 20, at least one duct 21 and at least one air intake device 201. The bottom box 20 is coupled to the bottom of the pillars 300 and has at least one air inlet 202 and at least one air outlet 203. An end of the duct 21 is coupled to the air outlet 203 and the duct 21 has a plurality of through holes 210 formed on the duct 21 so as to form a channel therein for guiding air. In addition, the duct 21 has a size corresponding to the size of the pillars 300. In this preferred embodiment, the duct 21 is substantially in the shape of a rectangular box, and two ducts 21 are installed in the right panel 32 and the left panel 33 respectively, or combined on the door panel 31, and the ducts 21 are separated from the air outlet 203 when the door panel 31 is opened and the ducts 21 are coupled to the air outlet 203 when the door panel 31 is closed. Therefore, the duct 21 will not occupy any using space inside the industrial cabinet 3 and the position and size of the duct 21 can be adjusted flexibly to achieve the best cool house effect.

The air intake device 201 is installed inside the bottom box 20 and provided for producing a suction force to suck cold air proximate to the ground from the air inlet 202, and the cold air is passed through the duct 21 and delivered to the installation spaces uniformly to enhance the cool house effect. In addition, the air inlet 202 is formed at the bottom of the bottom box 20, and the air outlet 203 is formed at the top of the bottom box 20 and situated at a position corresponding to the duct 21, and a gauze or a filter can be installed to the air inlet 202, the air outlet 203 and the wind outlet portion 35 to reduce the chance for external dust or foreign substances to enter the industrial cabinet 3 and prevent the electronic equipments 4 from being damaged by the dust or foreign substances.

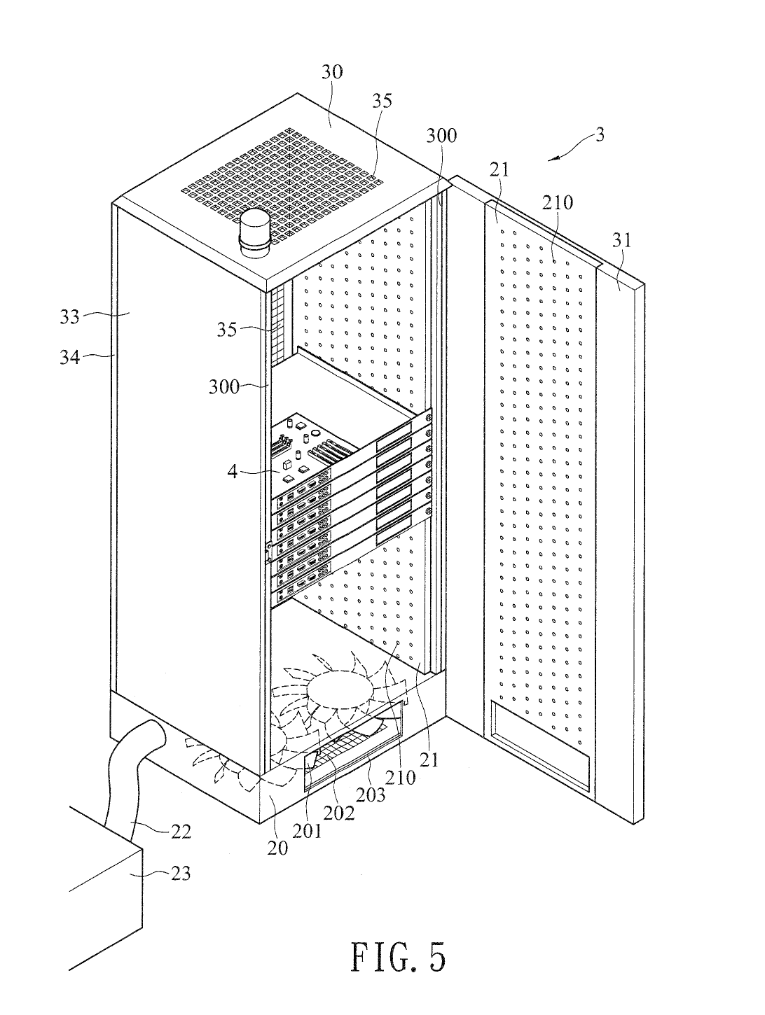

With reference to FIG. 5 for a schematic view of another exemplary embodiment of the invention, the bottom box 20 contains two air intake devices 201 installed therein to enhance the air intake effect. The air distribution structure 2 further comprises an airflow guide tube 22 with an end coupled to the air inlet 202 and the other end coupled to a cooling system 23, so that the air intake device 201 can guide cold air directly to further enhance the cool house effect.

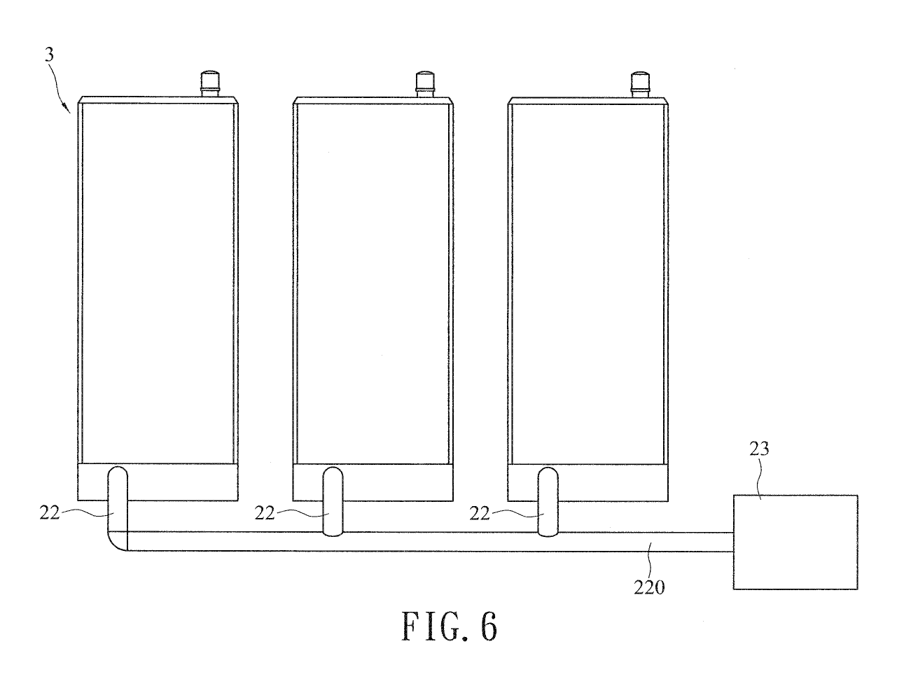

With reference to FIG. 6 for a schematic view of a further exemplary embodiment of the invention, if the industrial cabinets 3 are combined for use, the cooling system 23 delivers cold air of low temperature through the airflow guide tubes 22 of the industrial cabinets 3 to each air distribution structure 2, or the cooling system 23 can connect an air distribution tube 220 to the airflow guide tubes 22 and then connect the air distribution structures 2, so that the industrial cabinets can be connected adjacent to each other to capture the cold air.

What is claimed is:

1. An air distribution structure of an industrial cabinet, installed inside the industrial cabinet, and the industrial cabinet having pillars separately and vertically disposed at four corners of a top panel to define four sides, a door panel disposed at a front side, and a right panel, a left panel and a rear panel disposed on the remaining three sides respectively, and a plurality of electronic equipments disposed among the pillars to form a plurality of installation spaces, and the air distribution structure comprising:
a bottom box, coupled to the bottom of the pillars, and having at least one air inlet and at least one air outlet;
at least one duct, installed in at least one of the side panels other than the rear panel and disposed between the pillars, and an end of the duct being coupled to the air outlet, and a plurality of through holes being formed on a surface of the duct, and the duct having a size corresponding to the size of the pillars; and
at least one air intake device, installed inside the bottom box, for producing a suction force to suck cold air near the ground from the air inlet, and the cold air being guided by the duct and delivered into the installation spaces uniformly.

2. The air distribution structure of an industrial cabinet as recited in claim 1, wherein the air intake device is a vortex fan.

3. The air distribution structure of an industrial cabinet as recited in claim 1, further comprising an airflow guide tube with an end coupled to the air inlet, and the other end coupled to a cold air source.

4. The air distribution structure of an industrial cabinet as recited in claim 3, further comprising an air distribution tube coupled to the airflow guide tubes and the cold air source if a plurality of industrial cabinets is used.

5. The air distribution structure of an industrial cabinet as recited in claim 1, wherein the duct is coupled to the door panel, and an end of the duct is separated from the air outlet when the door panel is opened, and coupled to the air outlet when the door panel is closed.

6. The air distribution structure of an industrial cabinet as recited in claim 1, wherein the duct comes with a quantity of two and the ducts are installed in the left panel and the right panel respectively, and an end of each duct is coupled to the air outlet.

7. The air distribution structure of an industrial cabinet as recited in claim 1, further comprising at least one wind outlet portion disposed on the rear panel.

8. The air distribution structure of an industrial cabinet as recited in claim 1, further comprising at least one wind outlet portion disposed on the top panel.
